(19) United States
(12) Patent Application Publication
(10) Pub. No.: US 2013/0335670 A1
(43) Pub. Date: Dec. 19, 2013

(54) PLANAR DISPLAY DEVICE

(71) Applicants: WINTEK CORPORATION, Taichung City (TW); DongGuan Innolife Import and Export Trading Co., Ltd., Dongguan City (CN)

(72) Inventors: Hieng-Hsiung Huang, Hsinchu City (TW); Jin Ya Nie, Nanxiong City, Guangdong Province (CN); Ming-Chuan Lin, Taichung City (TW); Pao-Tien Lee, New Taipei City (TW); Yin-Wen Huang, New Taipei City (TW); Min-An Wu, New Taipei City (TW)

(21) Appl. No.: 13/917,659

(22) Filed: Jun. 14, 2013

(30) Foreign Application Priority Data
Jun. 15, 2012 (CN) 201210199971.4

(51) Int. Cl. H05K 5/03; H05K 5/00; F21V 33/00

(52) U.S. Cl. CPC H05K 5/03; F21V 33/0052; H05K 5/0017
USPC 349/58; 362/97.1; 361/679.01

(57) ABSTRACT

A planar display device includes a transparent cover plate and a display unit. The transparent cover plate has an attaching surface. The display unit is fully attached to the attaching surface of the transparent cover plate.

### BACKGROUND OF THE INVENTION

1. Field of the Invention

The present invention relates to a planar display device, and more specifically, to a planar display device of fully attaching a display unit to a transparent cover plate.

2. Description of the Prior Art

In general, a conventional planar display device (e.g. a planar TV, a planar computer screen) has a border region with no display function at its periphery, and the border region usually influences the outer appearance of the planar display device. Thus, how to narrow the border region of the planar display device is a major concern to the structural design of the planar display device.

A conventional casing assembly design of the planar display device involves utilizing a front frame and a rear cover to contain the major components (e.g. a display panel and a backlight module) inside the planar display device. However, disposal of the front frame could not only constrain the border narrowing design of the planar display device, but also be disadvantageous to placement or hanging of the planar display device since the overall thickness of the planar display device could be accordingly increased.

### SUMMARY OF THE INVENTION

The present invention discloses a planar display device. The planar display device includes a transparent cover plate and a display unit. The transparent cover plate has an attaching surface. The display unit is fully attached to the attaching surface of the transparent cover plate.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a front view of a planar display device according to an embodiment of the present invention.

FIG. 2 is a partial sectional diagram of the planar display device in FIG. 1 along a sectional line A-A′.

FIG. 3 is a partial sectional diagram of a planar display device according to another embodiment of the present invention.

### DETAILED DESCRIPTION

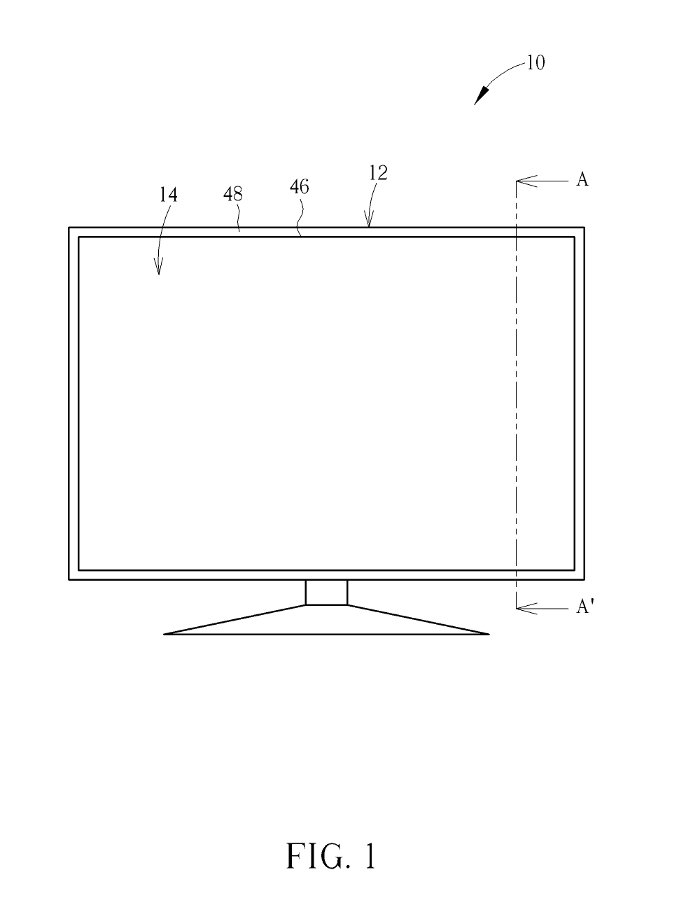

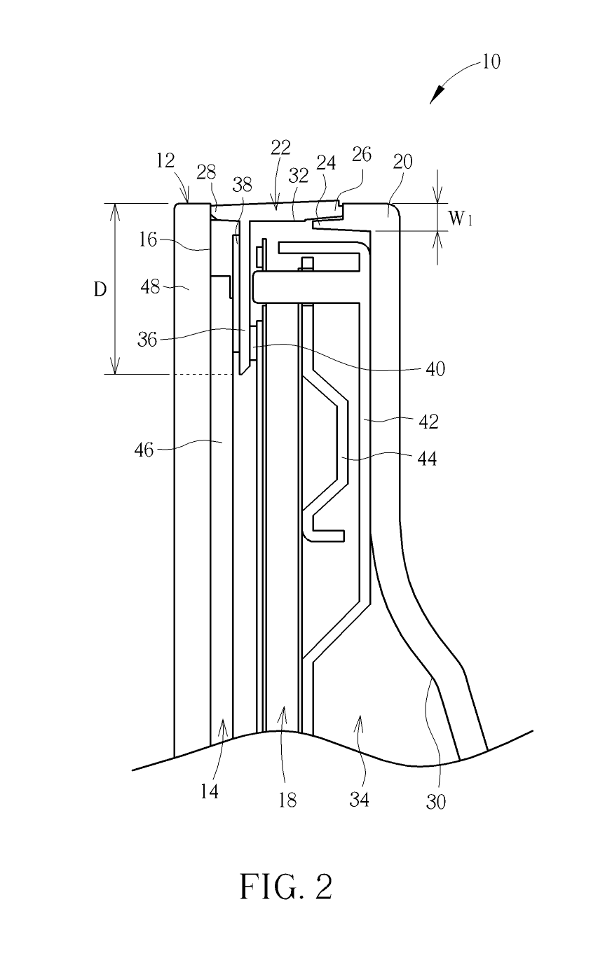

Please refer to FIG. 1 and FIG. 2. FIG. 1 is a front view of a planar display device 10 according to an embodiment of the present invention. FIG. 2 is a partial sectional diagram of the planar display device 10 in FIG. 1 along a sectional line A-A′. In this embodiment, the planar display device 10 could be preferably a flat TV, but not limited thereto. That is to say, the planar display device 10 could also be other commonly-seen planar display apparatus, such as a flat computer screen. As shown in FIG. 1 and FIG. 2, the planar display device 10 includes a transparent cover plate 12 and a display unit 14. The transparent cover plate 12 has an attaching surface 16. The display unit 14 is fully attached to the attaching surface 16 of the transparent cover plate 12. The transparent cover plate 12 could be a strengthened glass substrate with preferable scratch resistance and high hardness. The display unit 14 could be preferably an LCD (Liquid Crystal Display) panel or an OLED (Organic Light Emitting Diode) panel. The display unit 14 could be fully attached to the attaching surface 16 of the transparent cover plate 12 by OCA (Optical Clear Adhesive) or LOCA (Liquid Optical Clear Adhesive) so as to make images displayed by the display unit 14 have a higher brightness.

In the following, the other components of the planar display device 10 are described in detail on premise that the display unit 14 is an LCD panel. As shown in FIG. 2, the planar display device 10 could further include a backlight module 18, a rear cover 20, and an intermediate frame 22. The backlight module 18 is disposed between the display unit 14 and the rear cover 20 for providing light to the display unit 14. As for the related description for the components of the backlight module 18, it is commonly seen in the prior art and therefore omitted herein. The rear cover 20 has a first periphery connecting portion 24. The intermediate frame 22 has a second periphery connecting portion 26 and a third periphery connecting portion 28 opposite to the second periphery connecting portion 26. The second periphery connecting portion 26 is disposed around the first periphery connecting portion 24. The third periphery connecting portion 28 is disposed around a periphery of the attaching surface 16 of the transparent cover plate 12 (as shown in FIG. 2). To be more specific, via the intermediate frame 22 being respectively connected to the transparent cover plate 12 and the rear cover 20, the attaching surface 16 of the transparent cover plate 12 could define a containing space 34 cooperatively with an inner surface 32 of the intermediate frame 22 and an inner surface 30 of the rear cover 20 corresponding to the attaching surface 16 for containing the display unit 14 and the backlight module 18. To be noted, the planar display device 10 could utilize a connection design commonly seen in the prior art, such as a structural engagement design or a screw locking design, to connect the intermediate frame 22 to the transparent cover plate 12 and the rear cover 20 respectively.

More detailed description for connection of the intermediate frame 22 and the display unit 14 is provided as follows. As shown in FIG. 2, the intermediate frame 22 could further have a protruding portion 36. The protruding portion 36 extends from the inner surface 32 of the intermediate frame 22 toward the containing space 34 for supporting the display unit 14. In this embodiment, for further preventing damage of the film components (e.g. a reflection film, a diffuser film, and a brightness enhancement film) of the backlight module 18 and the display unit 14 caused by collision of the protruding portion 36 with the display unit 14 and the backlight module 18, a buffer layer with twin adhesives arranged at opposite surfaces of the buffer layer could be respectively disposed between the protruding portion 36 and the display unit 14 and between the protruding portion 36 and the backlight module 18. For example, the intermediate frame 22 could further have a first sponge buffer layer 38 and a second sponge buffer layer 40. The first sponge buffer layer 38 is attached between the display unit 14 and the protruding portion 36. The second sponge buffer layer 40 is attached between the protruding portion 36 and the backlight module 18. The first sponge buffer layer 38 is preferably made of organic rayon material, and the second sponge buffer layer 40 is preferably made of EVA (Ethylene-Vinyl Acetate) material. Accordingly, disposal of the first sponge buffer layer 38 and the second sponge buffer layer 40 could efficiently prevent collide of the protruding portion 36 with the display unit 14 and the backlight module 18 for protection of the display unit 14 and the backlight module 18.

Furthermore, the planar display device 10 could further include a back board 42 and a support frame 44. The back board 42 is disposed between the backlight module 18 and the rear cover 20. The support frame 44 is fixed to the back board 42 for holding the backlight module 18 on the back board 42. In this embodiment, the support frame 44 could be preferably fixed to the back board 42 in a screw locking manner.

In the following, assembly of the planar display device 10 is described. Firstly, the display unit 14 could be fully attached to the attaching surface 16 of the transparent cover plate 12 by an optical clear adhesive attachment technique. Next, the transparent cover plate 12 with the display unit 14 attached thereon could be placed on the protruding portion 36 of the intermediate frame 22 after the first sponge buffer layer 38 and the second sponge buffer layer 40 are attached to the protruding portion 36 respectively, and then the third periphery connecting portion 38 of the intermediate frame 22 could be disposed around the periphery of the attaching surface 16 of the transparent cover plate 12, so as to complete assembly of the display unit 14 and the transparent cover plate 12. Subsequently, the support frame 44 could be screwed on the back board 42 and then the components (e.g. a reflection film, a light guide plate, a diffuser film, a brightness enhancement film) of the backlight module 18 are placed on the support frame 44 sequentially. Finally, after the back board 42 assembled with the backlight module 18 is placed on the intermediate frame 22 having the display unit 14 and the transparent cover plate 12 attached thereon, the rear cover 20 could be utilized to cover the back board 42, and then the first periphery connecting portion 24 of the rear cover 20 could be connected to the second periphery connecting portion 26, so as to complete assembly of the planar display device 10. To be noted, the assembly sequence of the planar display device 10 is not limited to the aforesaid embodiment and varies with different practical manufacturing needs of the planar display device 10.

In summary, via the aforesaid design in which the display unit 14 is fully attached to the transparent cover plate 12 and the intermediate frame 22 is utilized to connect to the transparent cover plate 12 and the rear cover 20, assembly of the planar display device 10 could be completed by only utilizing the intermediate frame 22 to respectively connect to the display unit having the transparent cover plate 12 fully attached thereon without additionally utilizing a front frame. In such a manner, the present invention could not only efficiently reduce the overall thickness of the planar display device 10 to make placement or hanging of the planar display device 10 more convenient, but also increase the structural strength of the display unit 14 by full attachment of the transparent cover plate 12 to the display unit 14.

Furthermore, since there is no need to additionally dispose the front frame on the transparent cover plate 12, meaning that the border design of the transparent cover plate 12 could be no longer constrained by disposal of the front frame, the present invention could further achieve the purpose that the planar display device 10 could have a narrow border region with no frame member disposed at its front surface and periphery.

In practical application, the border width of the transparent cover plate 12 relates to the size of the visible region of the display unit 14 and the connection width of the intermediate frame 22 and the rear cover 20. For example, as shown in FIG. 2, the display unit 14 could have a visible region 46 and the transparent cover plate 12 could further have a border decoration region 48. In this embodiment, the width of the border decoration region 48 could be less than or equal to a distance D between the edge of the transparent cover plate 12 and the edge of the visible region 46 of the display unit 14 (in FIG. 2, the width of the border decoration region 48 is depicted to be equal to the distance D as an example), and greater than or equal to a connection thickness W₁ formed cooperatively by the second periphery connecting portion 26 of the intermediate frame 22 and the first periphery connecting portion 24 of the rear cover 20. According to the practical experience of the present invention, the width of the border decoration region 48 could be less than or equal to 8 mm so as to make the planar display device 10 have an excessively-narrow border region.

It should be mentioned that the planar display device provided by the present invention could also have a touch function. For example, the planar display device 10 could further include a touch sensor (not shown in the figures). The touch sensor could be disposed between the transparent cover plate 12 and the display unit 14. In this embodiment, the touch sensor could be preferably disposed on the transparent cover plate 12, but not limited thereto, meaning that the touch sensor could also be disposed on the display unit 14 instead. Via disposal of the touch sensor and the aforesaid design in which the planar display device 10 has no frame member at its front surface and periphery, the planar display device 10 could further has a flat touch function.

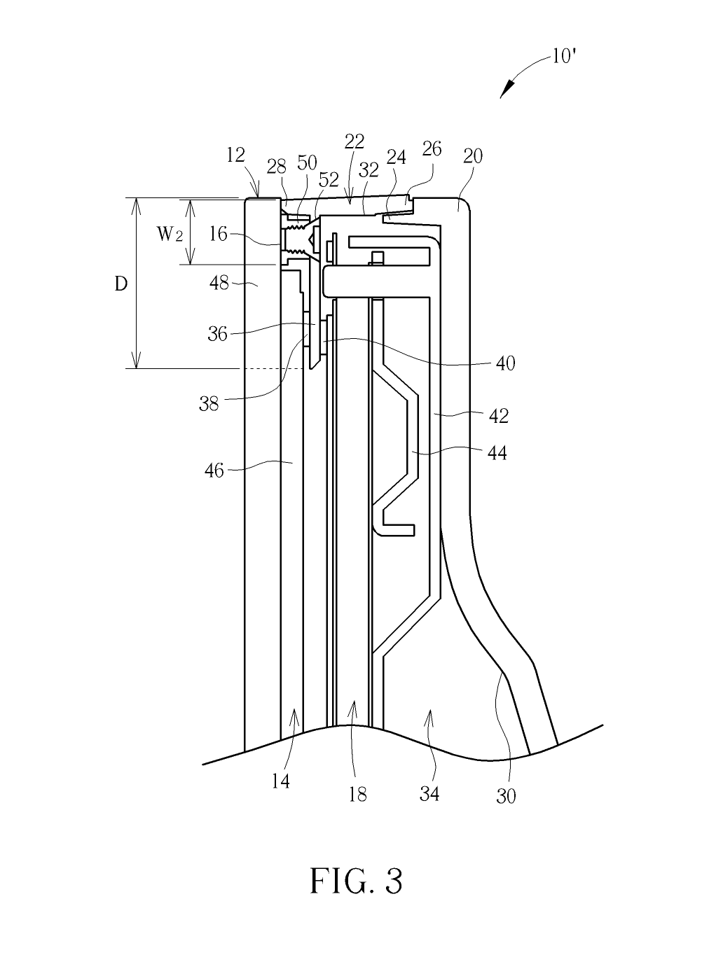

Furthermore, for further increasing the connection strength of the intermediate frame and the transparent cover plate, a screw locking design could be additionally applied to connection of the intermediate frame and the transparent cover plate. For example, please refer to FIG. 3, which is a partial sectional diagram of a planar display device 10′ according to another embodiment of the present invention. Components both mentioned in FIG. 3 and the aforesaid embodiment represent components with similar functions or structures. As for the related description for the structural design and the assembly process of the planar display device 10′, it could be reasoned according to the aforesaid embodiment and therefore omitted herein. As shown in FIG. 3, the transparent cover plate 12 of the planar display device 10′ could further have a screw connecting member 50 (e.g. a screw post). The screw connecting member 50 is fixed to the transparent cover plate 12 corresponding to the protruding portion 36 by a commonly-seen connecting design, such as a liquid adhesive attachment design. In such a manner, the protruding portion 36 could utilize a screw 52 to be screwed in the screw connecting member 50 so that the transparent cover plate 12 could be fixed to the intermediate frame 22 more firmly. To be noted, as shown in FIG. 3, the width of the border decoration region 48 could be designed to be less than or equal to the distance D (in FIG. 3, the width of the border decoration region 48 is depicted to be equal to the distance D as an example), and greater than or equal to a connection thickness W₂ formed cooperatively by the screw connecting member 50 and the third periphery connecting portion 28 of the intermediate frame 22 on the transparent cover plate 12. Similarly, according to the practical experience of the present invention, the width of the border decoration region 48 could be less than or equal to 8 mm so as to make the planar display device 10′ have an excessively-narrow border region.

Compared with the prior art, the present invention utilizes the design in which the display unit is fully attached to the transparent cover plate and the intermediate frame is utilized to connect to the transparent cover plate and the rear cover respectively, to complete assembly of the planar display device without additionally utilizing a front frame. In such a manner, the present invention could not only efficiently reduce the overall thickness of the planar display device to make placement or hanging of the planar display device 10 more convenient, but also make the planar display device have a narrow border region with no frame member at its front surface and periphery. Furthermore, if the touch sensor is additionally disposed between the transparent cover plate and the display unit, the present invention could further make the planar display device have a flat touch function, so as to improve convenience of the planar display device in use.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A planar display device comprising:
a transparent cover plate having an attaching surface; and
a display unit fully attached to the attaching surface of the transparent cover plate.

2. The planar display device of claim 1 further comprising:
a rear cover having a first periphery connecting portion; and
an intermediate frame having a second periphery connecting portion and a third periphery connecting portion opposite to the second periphery portion, the second periphery connecting portion being disposed around the first periphery connecting portion, the third periphery connecting portion being disposed around a periphery of the attaching surface of the transparent cover plate;
wherein the attaching surface of the transparent cover plate defines a containing space cooperatively with an inner surface of the rear cover corresponding to the attaching surface and an inner surface of the intermediate frame for containing the display unit.

3. The planar display device of claim 2, wherein the display unit has a visible region, the transparent cover plate further has a border decoration region, and a width of the border decoration region is greater than or equal to a connection thickness formed cooperatively by the second periphery connecting portion of the intermediate frame and the first periphery connecting portion of the rear cover and is less than or equal to a distance between an edge of the transparent cover plate and an edge of the visible region of the display unit.

4. The planar display device of claim 3, wherein the width of the border decoration region is less than or equal to 8 mm.

5. The planar display device of claim 2, wherein the intermediate frame further has a protruding portion, the protruding portion extends from the inner surface of the intermediate frame toward the containing space, and the display unit is fixed between the protruding portion and the transparent cover plate.

6. The planar display device of claim 5, wherein the intermediate frame further has a first sponge buffer layer, and the first sponge buffer layer is attached to the display unit and the protruding portion.

7. The planar display device of claim 6, wherein the transparent cover plate further has a screw connecting member, the screw connecting member is fixed to the transparent cover plate corresponding to the protruding portion, and the protruding portion is fixed to the screw connecting member in a screw locking manner.

8. The planar display device of claim 7, wherein the display unit has a visible region, the transparent cover plate further has a border decoration region, and a width of the border decoration region is greater than or equal to a connection thickness formed cooperatively by the screw connecting member and the third periphery connecting portion of the intermediate frame on the transparent cover plate and is less than or equal to a distance between an edge of the transparent cover plate and an edge of the visible region of the display unit.

9. The planar display device of claim 8, wherein the width of the border decoration region is less than or equal to 8 mm.

10. The planar display device of claim 5 further comprising:
a backlight module disposed in the containing space and located between the display unit and the rear cover.

11. The planar display device of claim 10 further comprising:
a back board disposed between the rear cover and the backlight module; and
a support frame fixed to the back board for holding the backlight module on the back board.

12. The planar display device of claim 11, wherein the intermediate frame further has a second sponge buffer layer attached to the protruding portion and the backlight module.

13. The planar display device of claim 1 further comprising:
a touch sensor disposed between the transparent cover plate and the display unit.

14. The planar display device of claim 1 further comprising:
a touch sensor disposed on the display unit.

15. The planar display device of claim 1, wherein the display unit is attached to the transparent cover plate by OCA (Optical Clear Adhesive) or LOCA (Liquid Optical Clear Adhesive).

16. The planar display device of claim 1, wherein the display unit is an LCD (Liquid Crystal Display) panel or an OLED (Organic Light Emitting Diode) panel.
